(19) United States
(12) Patent Application Publication
(10) Pub. No.: US 2019/0364675 A1
(43) Pub. Date: Nov. 28, 2019

(54) ADJUSTABLE FRAME AND ELECTRONIC DEVICE USING SAME

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventor: MING-CHUAN LEE, New Taipei (TW)

(21) Appl. No.: 16/119,724

(22) Filed: Aug. 31, 2018

(30) Foreign Application Priority Data
May 24, 2018 (CN) 201810513346.X

(51) Int. Cl. H05K 5/00; F16M 11/22; H05K 5/02

(52) U.S. Cl. CPC H05K 5/0017; F16M 11/22; H05K 5/0204; F16M 2200/08; H05K 5/0221; F16M 2200/028; H05K 5/0234

(57) ABSTRACT

An adjustable frame configured to support a display unit includes a support and an adjustable stand. The support is configured to mount the display unit thereon. The adjustable stand is fixed to the support. The adjustable stand includes an adjustable leg coupled to the adjustable stand. The adjustable leg includes a first leg and a second leg.

The first leg and the second leg are movable relative to each other. The adjustable leg has an opened position and a closed position. When the adjustable leg is in the opened position, at least one of the first leg and the second leg extends outwardly relative to the adjustable stand. When the adjustable leg is in the closed position, at least one of the first leg and the second leg is retracted inwardly relative to the adjustable stand.

### FIELD

The subject matter herein generally relates to an adjustable frame for adjusting a position of an electronic device.

### BACKGROUND

Large-sized electronic devices such as electronic whiteboards, televisions, or video displays are frequently mounted on a wall. However, wall-mounted electronic devices are difficult to move from place-to-place. These electronic devices may be made portable by mounting the electronic device on a movable stand. However, the movable stands are also large and generally take up too much space.

Therefore, there is room for improvement within the art.

### BRIEF DESCRIPTION OF THE DRAWINGS

Implementations of the present disclosure will now be described, by way of example only, with reference to the attached figures.

FIG. 1 shows an electronic device mounted on an adjustable frame in accordance with an embodiment of the present disclosure, the adjustable frame in an opened position.

FIG. 2 is similar to FIG. 1, but shows the adjustable frame in a closed position.

FIG. 3 shows a first embodiment of the adjustable frame in the opened position.

FIG. 4 is similar to FIG. 3, but shows the adjustable frame in the closed position.

FIG. 5 shows a second embodiment of the adjustable frame in the opened position.

FIG. 6 is similar to FIG. 5, but shows the adjustable frame in the closed position.

FIG. 7 shows a third embodiment of the adjustable frame in the opened position.

FIG. 8 is similar to FIG. 7, but shows the adjustable frame in the closed position.

### DETAILED DESCRIPTION

It will be appreciated that for simplicity and clarity of illustration, where appropriate, reference numerals have been repeated among the different figures to indicate corresponding or analogous elements. Additionally, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

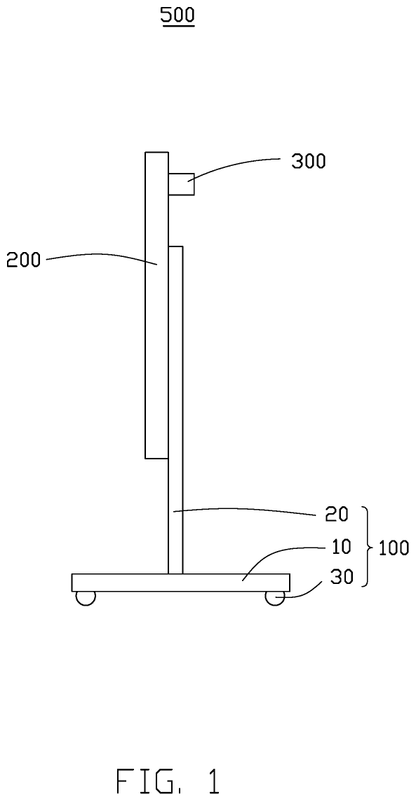

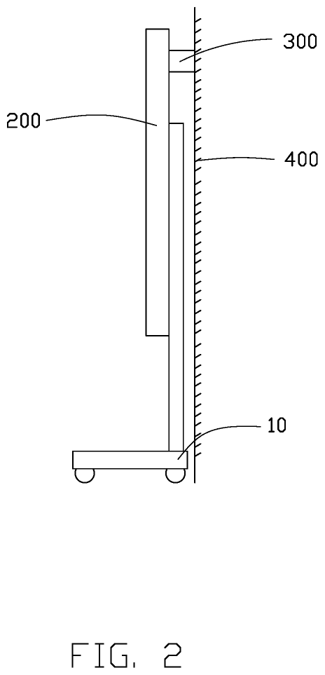

FIG. 1 and FIG. 2 show an embodiment of an electronic device 500 including an adjustable frame 100, a display unit 200, and a stop unit 300.

The adjustable frame 100 supports the display unit 200.

The stop unit 300 locks the display unit 200 to a wall 400 when the display unit 200 is adjacent to the wall 400.

In at least one embodiment, the display unit 200 can be an electronic whiteboard, television, or video display.

The adjustable frame 100 includes an adjustable stand 10, a support 20, and wheels 30.

The support 20 is fixed to the adjustable stand 10 and supports the display unit 200. The wheels 30 are located on a bottom side of the adjustable stand 10 to allow the adjustable frame 100 to be conveniently moved.

FIGS. 1-4 show, in a first embodiment, the adjustable stand 10 includes an adjustable leg 130.

The adjustable leg 130 is coupled to the adjustable stand 10 and is movable between an opened position and a closed position.

When the adjustable leg 130 is in the opened position, the adjustable leg 130 is extended relative to the adjustable stand 10. When the adjustable leg 130 is in the closed position, the adjustable leg 130 is retracted relative to the adjustable stand 10 to reduce a length of the adjustable leg 130 and cause the adjustable stand 10 to take up less floor space.

The adjustable leg 130 includes a fixed first leg 1301 coupled to the base 110 and a movable second leg 1302 telescopically coupled to the fixed first leg 1301.

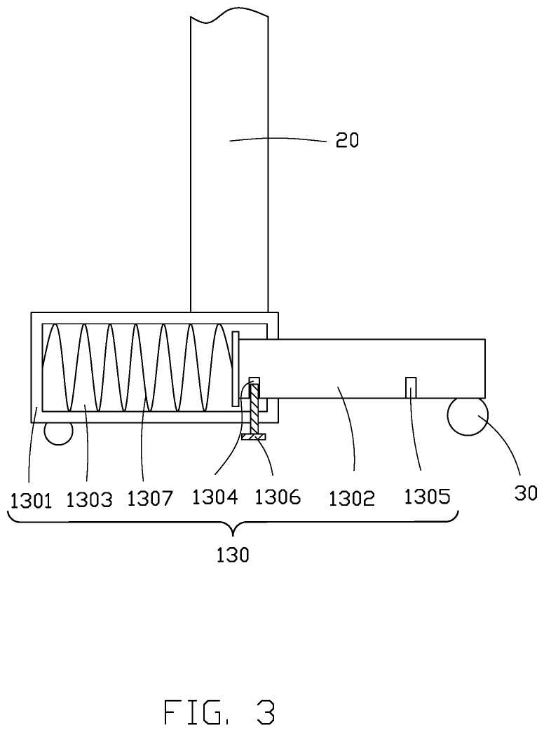

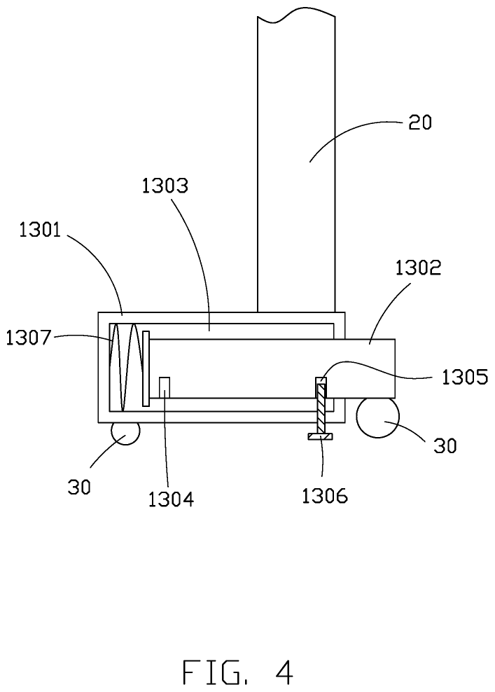

When the adjustable leg 130 is in the opened state (shown in FIGS. 1 and 3), the movable second leg 1302 is extended relative to the fixed first leg 1301. When the adjustable leg 130 is in the closed position (shown in FIGS. 2 and 4), the movable second leg 1302 is in a retracted position relative to the fixed first leg 1301, thereby reducing a length of the adjustable leg 130 and causing the adjustable stand 10 to take up less floor space.

The inside of the fixed first leg 1301 defines a receiving slot 1303. One end of the movable second leg 1302 is movably received within the receiving slot 1303.

When the adjustable leg 130 is in the opened position, the movable second leg 1302 extends out of the receiving slot 1303.

When the adjustable leg 130 is in the closed position, the movable second leg 1302 retracts into, and is partially received within, the receiving slot 1303.

The adjustable leg 130 further includes a first locking hole 1304, a second locking hole 1305, and a latching member 1306.

The first locking hole 1304 is defined in the movable second leg 1302 adjacent to the end of the movable second leg 1302 received in receiving slot 1303.

The second locking hole 1305 is defined in the end of movable second leg 1302 extending out of receiving slot 1303.

The latching member 1306 is located on the fixed first leg 1301 and can be latched with the first locking hole 1304 or the second locking hole 1305 to lock the movable second leg 1302 in the extended position or the retracted position relative to the fixed first leg 1301.

The adjustable leg 130 may further include a resilient member 1307. The resilient member 1307 is in the receiving slot and coupled between the fixed first leg 1301 and the movable second leg 1302.

When the movable second leg 1302 is moved to the retracted position relative to the fixed first leg 1301, the resilient member 1307 is compressed and generates a resilient force. When the latching member releases the movable second leg 1302, the resilient force of the resilient member 1307 drives the movable second leg 1302 into the extended position relative to the fixed first leg 1301, thereby placing the adjustable stand in the opened position.

The fixed first leg 1301 and the movable second leg 1302 are coaxial. The receiving slot 1303 is a blind hole defined in one end of the fixed first leg 1301 along an axis of the fixed first leg 1301.

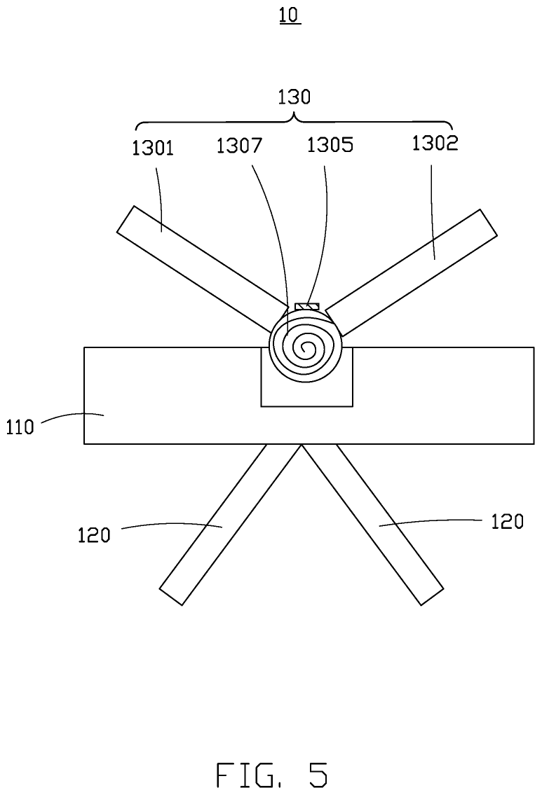

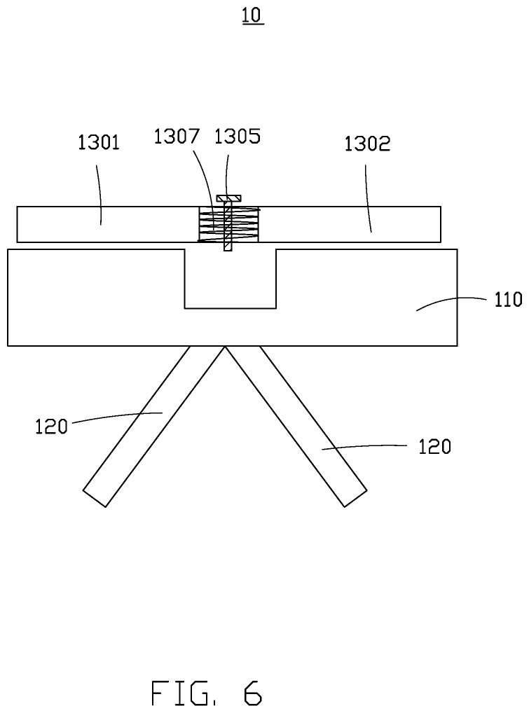

A second embodiment of the stand 10 is shown in FIGS. 5-6. The stand 10 in the second embodiment includes the adjustable leg coupled to a base 110. In the second embodiment, the adjustable leg 130 includes a movable first leg and a movable second leg.

In particular, the first leg 1301 and the second leg 1302 are straight, rigid objects. The adjustable leg 130 includes the resilient member 1307 and the latching member 1306. In the second embodiment, the resilient member 1307 is a torsional spring. One end of the movable second leg 1302 is coupled to one end of the movable first leg 1301 through the torsional spring.

When the adjustable leg 130 is in the closed position (shown in FIG. 6), the movable second leg 1302 is coaxial with the movable first leg 1301, the torsional spring generates a resilient force, and the latching member 1306 locks the torsional spring in place. In this position, both of the fixed first leg 1301 and the movable second leg 1302 can abut the base 110 to take up less space.

When the latching member 1306 is released, the resilient force of the torsional spring drives the movable first leg 1301 and the movable second leg 1302 to move to a predetermined angle relative to each other, thereby moving the adjustable leg 130 to the opened position.

The adjustable frame 100 further includes a pair of balancing legs 120. The pair of balancing legs 120 is fixed to another side of the base 110 for supporting the adjustable frame 100.

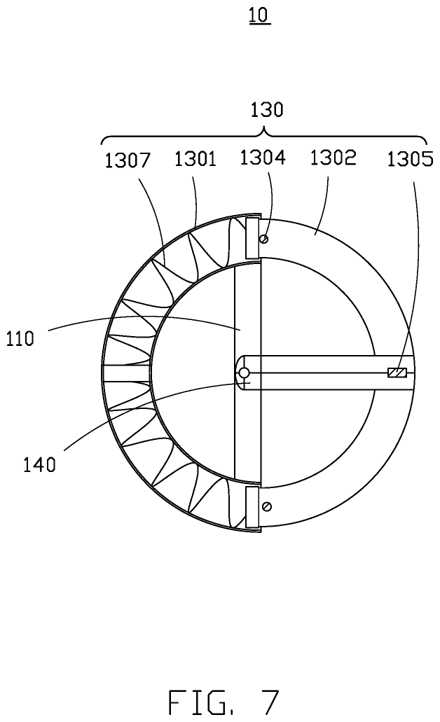

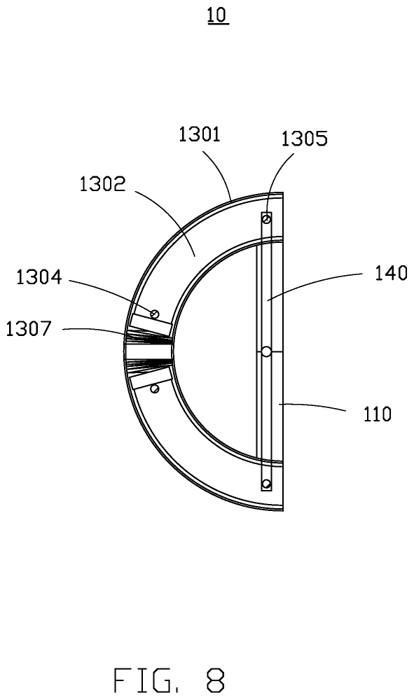

A third embodiment of the stand 10 is shown in FIGS. 7-8.

The adjustable leg 130 in the third embodiment includes a fixed first leg 1301 and a movable second leg 1302.

In particular, the fixed first leg 1301 and the movable second leg 1302 are both arcuate and have a common rotational axis. The movable second leg 1302 is bifurcated, and the fixed first leg 1301 defines a receiving slot (not labeled) in opposite ends of the fixed first leg 1301. The receiving slot is defined along an axis of the fixed first leg 1301 coaxial with the fixed first leg 1301. One section of the movable second leg 1302 is configured to be received into the receiving slot through one end of the fixed first leg 1301, and another section of the movable second leg 1302 is configured to be received into the receiving slot through the opposite end of the fixed first leg 1301.

The adjustable frame 100 further includes a positioning rod 140. The positioning rod 140 is bifurcated such that an end of one section of the positioning rod 140 is coupled to one section of the movable second leg 1302, and an end of the other section of the positioning rod 140 is coupled to the other section of the movable second leg 1302.

A first end of both sections of the positioning rod 140 is rotationally coupled to the base 110, and a second end of both sections of the positioning rod 140 includes a fixing portion (not shown) for fixing the two sections of the movable second leg 1302 together.

The fixed first leg 1301 includes two sections, and the resilient member 1307 is received in both sections of the fixed first leg 1301. One section of the fixed first leg 1301 receives one corresponding section of the movable second leg 1302, and the other section of the fixed first leg 1301 receives the corresponding other section of the movable second leg 1302.

The resilient member 1307 is a compression spring and is received in the receiving slot 1303 in both sections of the fixed first leg 1301. When the two sections of the movable second leg 1302 are not received within the receiving slots 1303, the resilient members 1307 are not compressed (shown in FIG. 7). When the two sections of the movable second leg 1302 are received within the receiving slots 1303, the resilient members 1307 are compressed (shown in FIG. 8).

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

1. An adjustable frame configured to support a display unit, the adjustable frame comprising:
a support configured to mount the display unit thereon;
an adjustable stand, the support fixed to the adjustable stand, the adjustable stand comprising:
an adjustable leg coupled to the adjustable stand, the adjustable leg comprising a first leg and a second leg, the first leg and the second leg movable relative to each other, and the adjustable leg having an opened position and a closed position; wherein:
when the adjustable leg is in the opened position, at least one of the first leg and the second leg extends outwardly relative to the adjustable stand; and
when the adjustable leg is in the closed position, at least one of the first leg and the second leg is retracted inwardly relative to the adjustable stand.

2. The adjustable frame of claim 1, wherein:
the first leg is fixed to one side of the support; and
the second leg is telescopically coupled to the first leg; wherein:
when the adjustable leg is in the opened position, the second leg is extended relative to the first leg; and
when the adjustable leg is in the closed position, the second leg is in a retracted position relative to the first leg.

3. The adjustable frame of claim 2, wherein:
the first leg defines a receiving slot in one end thereof, and one end of the second leg is movably received within the receiving slot;
when the adjustable leg is in the opened position, the second leg extends out of the receiving slot; and
when the adjustable leg is in the closed position, the second leg retracts into the receiving slot and is partially received within the receiving slot.

4. The adjustable frame of claim 3, wherein the adjustable leg further comprises:
a first locking hole defined in the second leg adjacent to the end of the second leg received in the receiving slot;
a second locking hole defined in the end of the second leg extending out of the receiving slot; and
a latching member located on the first leg and configured to be latched in the first locking hole or the second locking hole to lock the second leg in the extended position relative to the first leg or in the retracted position relative to the first leg.

5. The adjustable frame of claim 4, wherein the adjustable leg further comprises:
a resilient member coupled between the first leg and the second leg; wherein:
when the second leg is in the retracted position relative to the first leg, the resilient member is compressed and generates a resilient force; and
when the latching member releases the second leg, the resilient force of the resilient member drives the second leg into the extended position relative to the first leg.

6. The adjustable frame of claim 5, wherein:
the first leg and the second leg are arranged coaxial relative to each other; and
the receiving slot is a blind hole defined along an axis of the first leg.

7. The adjustable frame of claim 1, wherein:
the adjustable frame further comprises a base and a positioning rod;
the first leg is fixed to one side of the base;
the first leg and the second leg are arranged in an arcuate relationship having a common rotational axis;
the receiving slot is defined coaxially with the first leg;
a first end of the positioning rod is rotationally coupled to the base, and a second end of the positioning rod comprises a fixing portion fixed to the second leg.

8. The adjustable frame of claim 1, wherein:
the adjustable frame further comprises a base, a torsional spring, and a latching member;
the first leg and the second leg are straight, rigid objects;
a first end of the second leg is coupled to the first leg through the torsional spring;
when the adjustable leg is in the opened position, the first leg and the second leg are coaxial with each other, the torsional spring generates a resilient force, and the torsional spring is locked in position by the latching member;
when the latching member is removed, the resilient force of the torsional spring drives the first leg and the second leg into a position having a predetermined angle relative to each other, and the adjustable leg is in the closed position.

9. The adjustable frame of claim 8, wherein the adjustable frame further comprises a balancing leg fixed to another side of the base.

10. An electronic device comprising:
a display unit;
an adjustable frame configured to support the display unit; and
a stop unit configured to lock the display unit to a wall when the display unit is adjacent to the wall; wherein the adjustable frame comprises:
a support configured to mount the display unit thereon;
an adjustable stand, the support fixed to the adjustable stand, the adjustable stand comprising:
an adjustable leg coupled to the adjustable stand, the adjustable leg comprising a first leg and a second leg, the first leg and the second leg movable relative to each other, and the adjustable leg having an opened position and a closed position; wherein:
when the adjustable leg is in the opened position, at least one of the first leg and the second leg extends outwardly relative to the adjustable stand; and
when the adjustable leg is in the closed position, at least one of the first leg and the second leg is retracted inwardly relative to the adjustable stand.

11. The electronic device of claim 10, wherein:
the first leg is fixed to one side of the support; and
the second leg is telescopically coupled to the first leg; wherein:
when the adjustable leg is in the opened position, the second leg is extended relative to the first leg; and
when the adjustable leg is in the closed position, the second leg is in a retracted position relative to the first leg.

12. The electronic device of claim 11, wherein:
the first leg defines a receiving slot in one end thereof, and one end of the second leg is movably received within the receiving slot;
when the adjustable leg is in the opened position, the second leg extends out of the receiving slot; and
when the adjustable leg is in the closed position, the second leg retracts into the receiving slot and is partially received within the receiving slot.

13. The electronic device of claim 12, wherein the adjustable leg further comprises:
a first locking hole defined in the second leg adjacent to the end of the second leg received in the receiving slot;
a second locking hole defined in the end of the second leg extending out of the receiving slot; and
a latching member located on the first leg and configured to be latched in the first locking hole or the second locking hole to lock the second leg in the extended position relative to the first leg or in the retracted position relative to the first leg.

14. The electronic device of claim 13, wherein the adjustable leg further comprises:
a resilient member coupled between the first leg and the second leg; wherein:
when the second leg is in the retracted position relative to the first leg, the resilient member is compressed and generates a resilient force; and
when the latching member releases the second leg, the resilient force of the resilient member drives the second leg into the extended position relative to the first leg.

15. The electronic device of claim 14, wherein:
the first leg and the second leg are arranged coaxial relative to each other; and
the receiving slot is a blind hole defined along an axis of the first leg.

16. The electronic device of claim 10, wherein:
the adjustable frame further comprises a base and a positioning rod;
the first leg is fixed to one side of the base;
the first leg and the second leg are arranged in an arcuate relationship having a common rotational axis;
the receiving slot is defined coaxially with the first leg;
a first end of the positioning rod is rotationally coupled to the base, and a second end of the positioning rod comprises a fixing portion fixed to the second leg.

17. The electronic device of claim 10, wherein:
the adjustable frame further comprises a base, a torsional spring, and a latching member;
the first leg and the second leg are straight, rigid objects;
a first end of the second leg is coupled to the first leg through the torsional spring;
when the adjustable leg is in the opened position, the first leg and the second leg are coaxial with each other, the torsional spring generates a resilient force, and the torsional spring is locked in position by the latching member;
when the latching member is removed, the resilient force of the torsional spring drives the first leg and the second leg into a position having a predetermined angle relative to each other, and the adjustable leg is in the closed position.

18. The electronic device of claim 10, wherein the adjustable frame further comprises a balancing leg fixed to another side of the base.
